(19) United States
(12) Patent Application Publication
(10) Pub. No.: US 2026/0087201 A1
(43) Pub. Date: Mar. 26, 2026

(54) Global Energy Management

(71) Applicant: QSecGrid, Inc., New York City, NY (US)

(72) Inventors: Gordon Winston, Katonah, NY (US); John-Philip Galinski, Forest Hills, NY (US); Nigel Walker, Ponteland (GB); Mark Thompson, Blyth (GB); Patrick J.D. Santos, Kirkland, WA (US)

(21) Appl. No.: 19/340,568

(22) Filed: Sep. 25, 2025

Related U.S. Application Data
(60) Provisional application No. 63/699,116, filed on Sep. 25, 2024.

(51) Int. Cl. G06F 30/20; G06Q 50/06

(52) U.S. Cl. CPC G06F 30/20; G06Q 50/06

(57) ABSTRACT

Global Energy Management comprising systems and methods to collect information about the configuration of energy resources and historicals about energy utilization as to make recommendations on how to optimize those energy resources are disclosed. Global Energy Management provides of adaptation regardless of location and whether or not data fields from the collecting information and historicals agree. Specifically, Global Energy Management makes use of ontology techniques to find corresponding data fields and makes use of software based estimation techniques such as interpolation, extrapolation, and statistical analysis to fill in missing data. Global Energy Management then creates energy profiles comprising data sets for different collections of energy resources, makes predictions and recommendations for the aggregated energy resources from the different collections, and in some cases automates the recommendations.

### CROSS-REFERENCE TO RELATED APPLICATIONS

This application claims priority to a commonly owned, U.S. Provisional Patent Application No. 63/699,116 , filed on Sep. 25, 2024, and titled “Global Energy Management”, which is herein incorporated by reference in its entirety.

### BACKGROUND OF THE INVENTION

Energy is critical for all. Energy is used for almost every activity ranging from communications, heating, transportation, and food preparation. In the case of commercial, industrial, and business operations, energy is used for production be it for manufactured goods or computer services. In short energy is at the heart of economic activity, it is critical for survival. However, for such a critical commodity, management of energy be it from the power grid to the end user is unnecessarily wasteful.

Parties and stakeholders ranging from consumers to government to utilities are interested in applying present day information technology to aging power grid infrastructure. One such effort is the transition from Distribution Network Operators (DNOs) to Distributed System Operators (DSOs). DNOs are traditional electric power grid utility operators that distribute centralized production, typically flowing unidirectionally from the central power grid to power consumers. In contrast DSOs are anticipated to take distributed generation such as home solar panels, and bidirectional transfer between microgrids which enable greater flexibility of power generation and power transfer, and therefore less waste in energy management.

To implement DSOs, technologies for virtualizing energy resources, load balancing those resources, and accounting for those resources are needed. Upon such novel deploying of such technologies, novel properties and use cases would emerge that not only provide better stewardship of energy but also give consumers more choices and options in management of energy.

Additionally, even when energy resources are virtualized, the parties funding and implementing the various virtualizations are unrelated to each other. Some virtualizations are done by different utilities, some by different customers, some by different vendors, and all by different parties. The result is that the various energy resources, even if virtualized, cannot be coordinated regardless of party and regardless of geographical distance. Complicating matters, because virtualizations are performed independently, they are performed inconsistently. Integration of different virtualizations should not involve sharing only data types and data fields in common, since that would result in integrations only at the lowest common denominator. Rather, virtualizations should be holistically integrated.

These and other issues impede an energy management transition to full digital control. What is needed is global energy management, not just in the sense of management across geographical distances, but in the sense of making use of all energy relevant information to manage and optimize energy utilization.

### BRIEF DESCRIPTION OF DRAWINGS

The detailed description is described with reference to the accompanying figures. In the figures, the left-most digits of a reference number identify the figure in which the reference number first appears. The same reference numbers in different figures indicate similar or identical items.

FIG. 1 is a context diagram for Global Energy Management.

FIG. 2 is a diagram of an exemplary environment for Global Energy Management.

FIG. 3 is a diagram of virtualization for Global Energy Management.

FIG. 4 is a diagram for Intelligent Energy Profiles for Global Energy Management.

FIG. 5 is a flow chart for utilizing Intelligent Energy Profiles for Global Energy Management.

FIG. 6 is a flow chart for Global Energy Management across changing and disparate collections of Intelligent Distributed Energy Resources.

FIG. 7 is a diagram of an exemplary Energy Accounting System for Global Energy Management.

### DETAILED DESCRIPTION OF THE INVENTION

### Energy Orchestration as a Service: The Context of Global Energy Management

Global Energy Management includes set of concepts around dynamically managing energy resources in the most efficient way. One concept is that of virtualization, where there are a set of physical energy resources that can be disaggregated into virtual resources and then reaggregated into a different set of virtual resources that optimize energy utilization for a particular location, be it residential such as private homes, commercial such as a business office or retail establishment or cinema, industrial such as a factory, or governmental/public such as schools or hospitals.

Concomitant with virtualization is a related concept around an adaptability infrastructure for physical energy resources. The idea is that allocation of an energy resource should not be limited to its physical attributes including capacity and location. Physical energy resources can include any producer (e.g., generator) or consumer (e.g., heat pump) of energy. These include without limitation batteries, thermostats, heat pumps, electric vehicle (EV) chargers, solar panels, wind turbines, and inverters. Consider where an individual home with its own meter has solar panels. If the individual home had excess electricity, it should be able to share the excess with other consumers that had need regardless that the solar panels were on someone else's house. However, this notion of sharing can be taken further.

Conversely consider a locality with a set of homes, each home with its own physical battery or batteries. Each battery could be disaggregated, that is have its energy storage capacity subdivided, and each subdivision allocated to a different consumer, regardless of location. For each consumer, the different subdivisions accessed could be combined together from a software perspective, i.e., for reporting, control, and management, and once combined could appear as a single battery. This process is known as reaggregation into a virtual energy resource, in this case a virtual battery.

Enabling disaggregation and reaggregation of physical energy resources into virtual energy resources frees energy resources to be allocated in the optimal configuration rather than being limited by physicality and locality. With energy resources available for virtualization, the following example scenarios are available. In a first scenario, a virtual battery with 10 GWh storage aggregated from remote batteries could be allocated just in time for a short period for a site in a locality where a storm is expected. In a second scenario, a virtual battery with 10 GWh storage capacity could be deployed for a set of homes for grid balancing, that is removing energy consumption spikes and troughs.

For purposes of terminology, when physical energy resources can be mixed and matched independent of location on the power grid, these resources are known as Distributed Energy Resources or DERs. Note that DERs can expose remote automation and network capabilities to enable remote control and monitoring (telemetry, historical data, and configuration data) via software application programming interfaces (APIs). When such APIs are available, they are known as Integrated DERs or IDERs. In some cases, physical energy resources might not be allocated to the power grid at large, but also not necessarily allocated to a single energy meter, but rather to a single geographic location. Examples include campuses, schools, factories, and apartment buildings. Such collections of physical energy resources that are controlled, monitored, and managed as a single entity are called microgrids.

Note that there are different ways to expose remote automation and network capabilities. For some devices, such as an inverter or heat pump, the device itself simply has an API. However, in other cases, such as arrays of solar panels and arrays of batteries, remote automation and control capabilities are not on each and every device, but may be aggregated and controlled through a single management system. For purposes of this application, the term IDER is intended to include any DER that is automated indirectly through a management system or other software, and any DER that is aggregated and jointly managed through a management system or other software.

The concept of virtualization is based on disaggregation and reaggregation through software. The notion is that through software, energy resources can be deployed upon need aka “just in time” according to some objective function (an objective function is a mathematical function to optimize to) such as functions to optimize for cost, to optimize for energy availability (consider rolling blackouts where the least number of people are affected, or high critical consumers such as hospitals are prioritized), or to optimize for least energy transfer latency (consider making a virtual battery resource available two hours in advance of a storm as opposed to two days). This deployment and redeployment according to some selected optimization principle is called Energy Orchestration. Where the software service implementing Energy Orchestration is via a subscription service, generally available from the cloud, the service is known as Energy Orchestration as a Service or (EOaaS). In this scheme, energy consumers can be understood to mediate energy consumption and generation via a virtual power plant comprised of a dynamically changing set of virtual energy resources.

Energy Orchestration therefore can be understood as just in time deployment and redeployment of virtual energy resources. Accordingly, just in time deployment relies on accurate predictions of generation and consumption. Predictions are implemented via statistical operation on telemetry of the various energy resources and usage patterns of consumers. Predictions may be performed via various statistical algorithms. Per recent developments, algorithms used include machine learning (ML) algorithms and generative AI (GenAI) approaches. Accordingly, Energy Orchestration that makes use of analytics to effect accurate predictions is called Global Energy Management. Collections of data that characterize customer usage as to support Global Energy Management are called Intelligent Energy Profiles.

IDERs which have software APIs can be connected to an energy management aggregation service. However, different IDERs, such as from different vendors, may have different APIs. As Energy Orchestration relies on accurate prediction, not only should the APIs be made compatible with each other, the APIs should provide the necessary telemetry to implement accurate predictions of energy consumption, generation, and other events such as downtime. This concept of adding software layers, called drivers, to make disparate IDERs appear consistent for purposes of Energy Orchestration and providing the telemetry supportive of Global Energy Management is called Adaptive Resource Interfacing.

As previously mentioned, Energy Orchestration optimizes according to an objective function. However, an objective function will rely on data that is aggregated and rolled up consistently. To this end, techniques to implement an Energy Accounting System are disclosed. Specifically, consumption and generation data is aggregated according to a Chart of Accounts, and accounting principles and techniques can be brought to bear to account for consumption (debits) and generation (credits). Using accounting principles, a reporting system can provide reliable and consistent reports and recommendations.

As a final point, Global Energy Management relies on collection of consumer data. Intelligent Energy Profiles can contain sensitive consumer information. Such data is properly subject to privacy and cybersecurity regulation. One key principle is that sensitive data is to be encrypted, and where a consumer requests, that sensitive data is to be timely deleted. However, where data relied upon for accurate predictions is deleted, other sources of information should be brought to bear, or otherwise predictions should fail gracefully, i.e., allowances for less accurate predictions should be made by the software infrastructure until the variances are no longer acceptable.

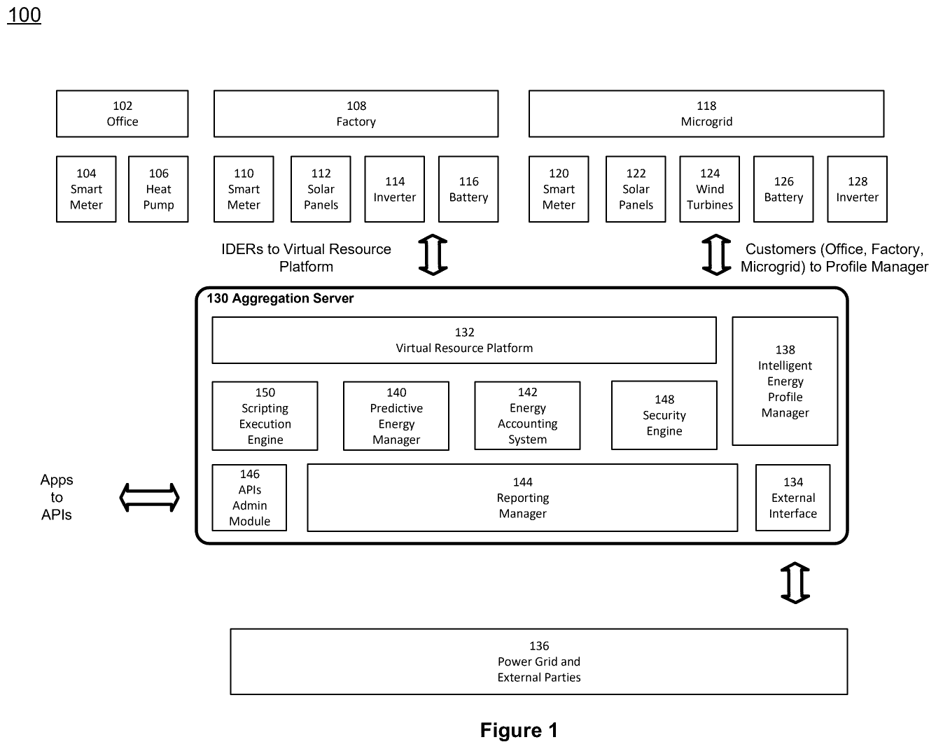

FIG. 1 is a context diagram 100 for Energy Orchestration including Global Energy Management and Intelligent Energy Profiles. One or more power utilities may serve a locality with an industrial campus that includes an office 102 with meter 104 heat pump 106 for an IDER. The industrial campus may also have a factory 108 with meter 110, solar panels 112, inverter 114, and battery 116 as IDERs. Note that a factory 108 in practice may have multiple meters. The industrial campus may also have a microgrid 118 with meter 120, solar panels 122, wind turbines 124, battery 126, and inverter 128 as IDERs.

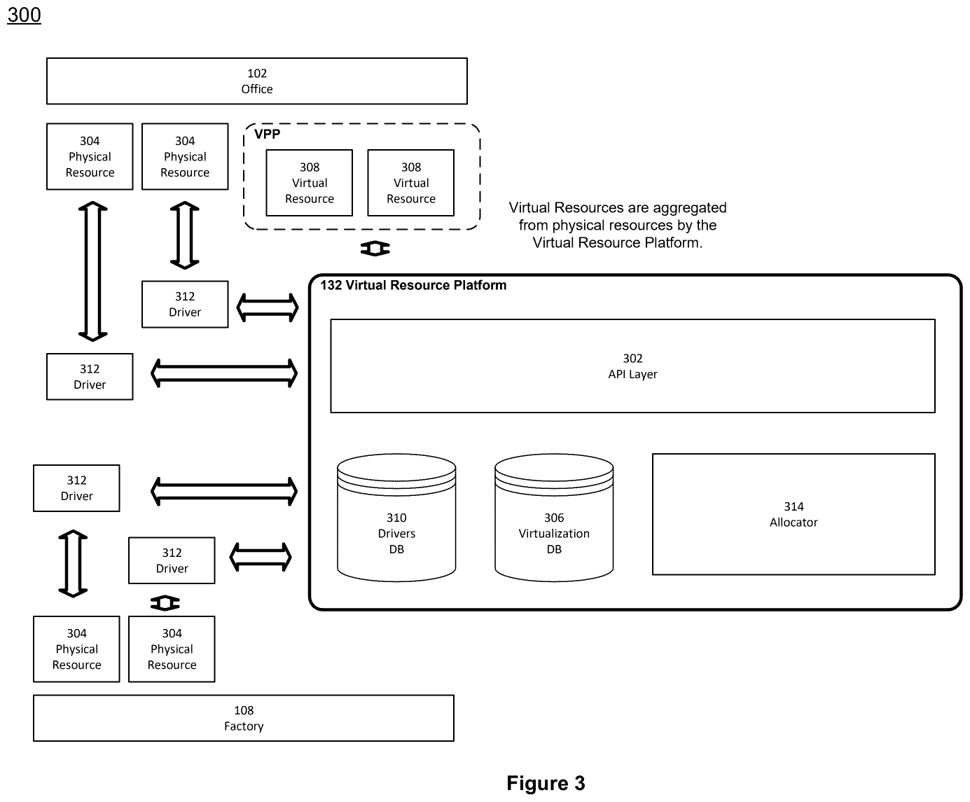

Energy Orchestration involves the disaggregation of the IDERs and reaggregation into virtual energy resources. This is effected via an Aggregation Server 130. Note that office 102 is strictly a consumer of energy with its heat pump 104. To achieve disaggregation, Aggregation Server 130 interfaces with all the IDERs via a software Virtual Resource Platform 132. Each of the IDERS may interface with a software driver that provides a consistent API supportive of Global Energy Management. The software driver is described in more detail with respect to FIG. 3 below. The Aggregation Server 130 has an External Interface 134 to enable information exchange and power exchange with the power grid 136 at large (such as energy suppliers and DNOs) and access to third-party information such as from other utilities (e.g., utilization data, tariff data), third-party billing systems, and third-party carbon data.

Note that in this scheme, office 102 and factory 108 are operating from their respective virtual power plants comprised of virtual energy resources served by the aggregation server 130. Indeed, the virtual energy resources are reaggregated from the physical energy resources. To achieve the reaggregation in providing virtual resources, office 102 and factory 108 may make requests of the Aggregation Server 130 for virtual resources. Alternatively, the Aggregation Server 130 may predict requirements and if so configured, may dynamically create and allocate a virtual resource. This is achieved via a software Intelligent Energy Profile Manager (Profile Manager for short) 138 that tracks both usage configuration, energy historical data, and potentially third party information such as market and environmental data sometimes summarized into a statistical summary called an Intelligent Energy Profile, which is then analyzed by a software Predictive Energy Manager 140 to determine resource needs for the consumers, here the office 102 and factory 108. The Predictive Energy Manager 140 acts as a forecasting engine for the Aggregation Server 130. Specifically, the Predictive Energy Manager 140 makes use of analytics algorithms, including machine learning and/or Generative AI algorithms, to determine one or more virtual energy resources to serve, and upon such determination accesses the Virtual Resource Platform 132 to redirect resources and update the Intelligent Energy Profile Manager 138, the Virtual Resource Platform 132 itself, and a software Energy Accounting System 142 as to what virtual resource the redirected resources are now allocated to.

The Energy Accounting System 142, tracks aggregations, disaggregations, events, and associates these not only with a user profile as managed by the Intelligent Energy Profile Manager 138, but also according to an accounting chart of accounts. A software Reporting Manager 144 provides an interface for external parties to query the Energy Accounting System 142 and the Aggregation Server 130 at large. Users of the Reporting Manager 144 include mobile applications for users, and an energy portal web site.

A privileged set of users are administrators for the aggregation server 130. A software Administrative Module 146 serves an administrative portal to enable diagnostics, monitoring, and maintenance of the virtual resources and operation of the Aggregation Server 130.

The concepts around virtualization, disaggregation, and reaggregation as well as Adaptive Resource Interfacing are described in further detail with respect to FIG. 3 below.

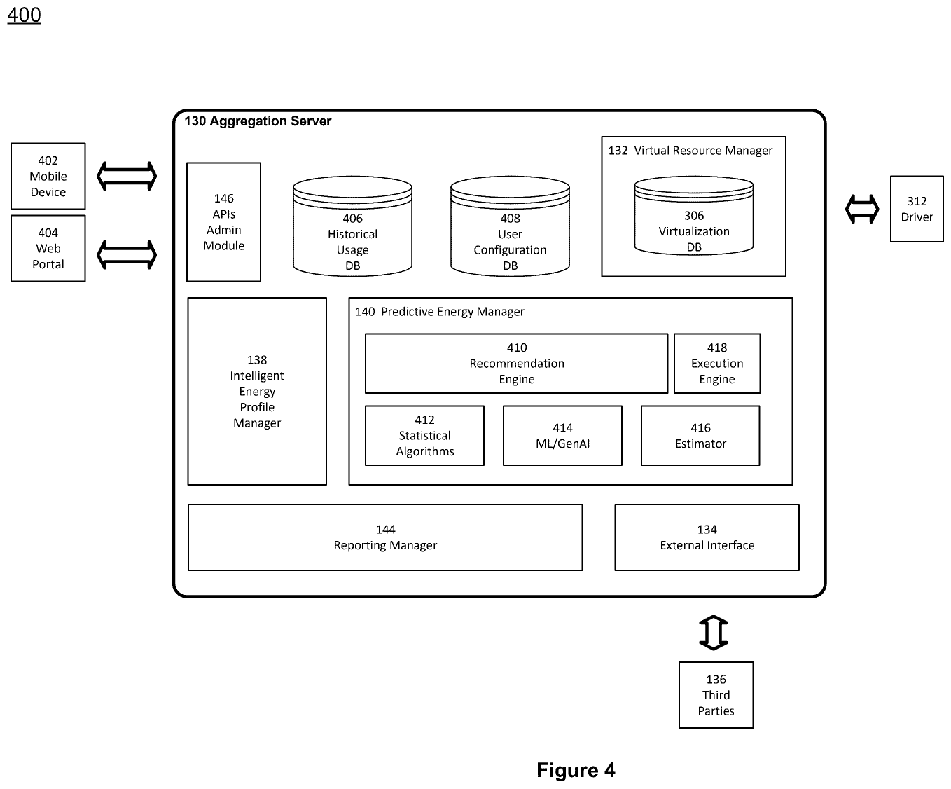

The concepts around, including with Intelligent Energy Profiles and Global Energy Management are described in further detail with respect to FIGS. 4, 5 and 6 below.

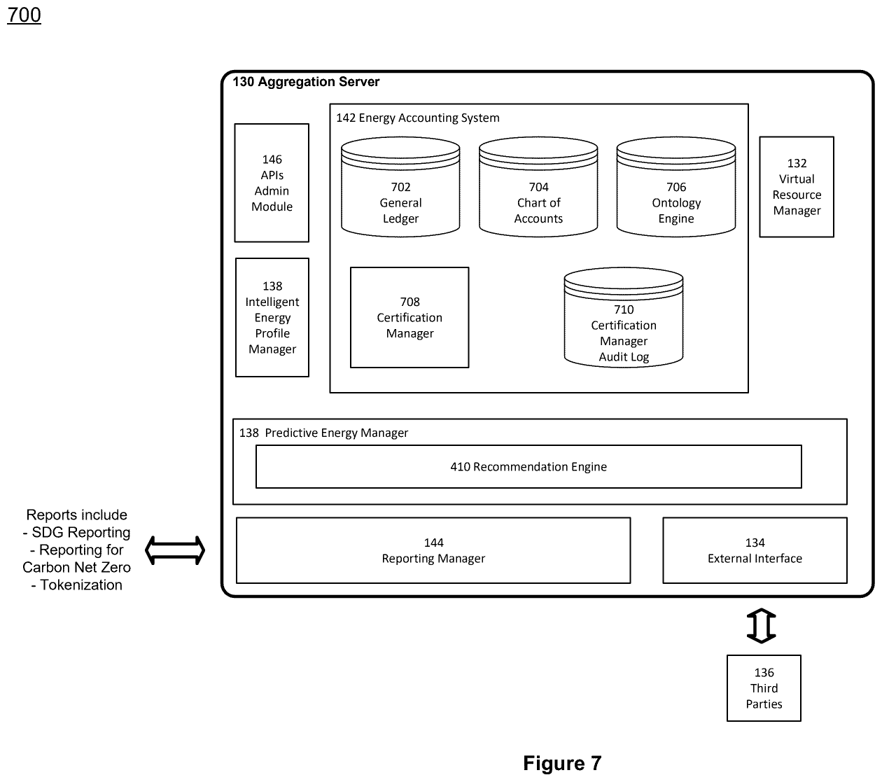

The concepts around an energy accounting system are described in further detail with respect to FIG. 7 below.

As mentioned above, users have the right to have data associated with their accounts deleted. Upon deletion the predictive capabilities of the Aggregation Server 130 should fail gracefully. The logic to support this is via a software Security Engine 148. The operation of the Security Engine 148 is described in further detail below.

The Aggregation Server 130 also provides a platform not just for reports but also for applications. To this end, a software Script Execution Engine 150 is included with the Aggregation Server 130 to run applications as embodied as scripts. Exemplary Business applications and the operation of the Script Execution Engine 150 is described in further detail below.

### Exemplary Environment for Global Energy Management

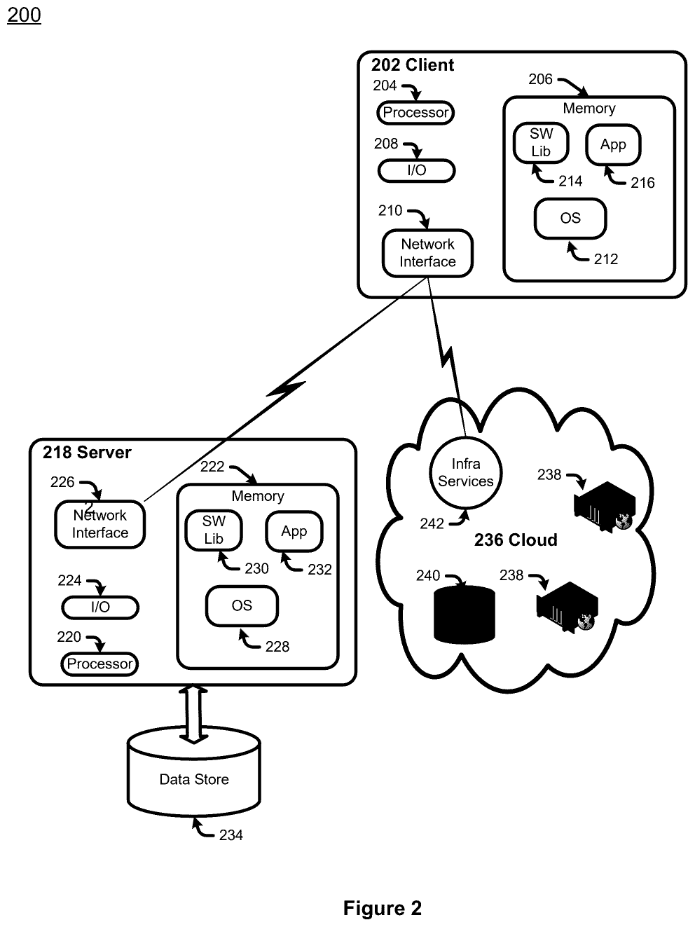

Before describing Global Energy Management in more detail, we describe in FIG. 2 an environment diagram 200 of an exemplary hardware, software, and communications computing environment.

### Client Platforms

The functionality for Global Energy Management is generally hosted on a computing device. Exemplary computing devices include without limitation personal computers, laptops, embedded devices, tablet computers, smart phones, and virtual machines. In many cases, computing devices are to be networked.

One computing device may be a client computing device 202. The client computing device 202 may have a processor 204 and a memory 206. The processor may be a central processing unit, a repurposed graphical processing unit, and/or a dedicated controller such as a microcontroller. The client computing device 202 may further include an input/output (I/O) interface 208, and/or a network interface 210. The I/O interface 208 may be any controller card, such as a universal asynchronous receiver/transmitter (UART) used in conjunction with a standard I/O interface protocol such as RS-232 and/or Universal Serial Bus (USB). The network interface 210 may potentially work in concert with the I/O interface 208 and may be a network interface card supporting Ethernet and/or Wi-Fi and/or any number of other physical and/or datalink protocols.

Memory 206 is any computer-readable media which may store software components including an operating system 212, software libraries 214, and/or software applications 216. In general, a software component is a set of computer executable instructions stored together as a discrete whole. Examples of software components include binary executables such as static libraries, dynamically linked libraries, and executable programs. Other examples of software components include interpreted executables that are executed on a run time such as servlets, applets, p-Code binaries, and Java binaries. Software components may run in kernel mode and/or user mode.

Computer-readable media includes at least two types of computer-readable media, namely computer storage media and communications media. Computer storage media includes volatile and non-volatile, removable, and non-removable media implemented in any method or technology for storage of information such as computer readable instructions, data structures, program modules, or other data. Computer storage media includes, but is not limited to, RAM, ROM, EEPROM, flash memory or other memory technology, CD-ROM, digital versatile disks (DVD), Blu-Ray™ or other optical storage, magnetic cassettes, magnetic tape, magnetic disk storage or other magnetic storage devices, or any other non-transmission medium that can be used to store information for access by a computing device. In contrast, communication media may embody computer readable instructions, data structures, program modules, or other data in a modulated data signal, such as a carrier wave, or other transmission mechanism. As defined herein, computer storage media does not include communication media.

### Server Platforms

A server 218 is any computing device that may participate in a network. The network may be, without limitation, a local area network (“LAN”), a virtual private network (“VPN”), a cellular network, or the Internet. The server 218 is similar to the host computer for the image capture function. Specifically, it will include a processor 220, a memory 222, an input/output interface 224, and/or a network interface 228. In the memory will be an operating system 228, software libraries 230, and server-side applications 232. Server-side applications include file servers and databases including relational databases. Accordingly, server 218 may have a data store 234 comprising one or more hard drives or other persistent storage devices.

One particular type of server 218 is an edge computing server. Edge computing servers provide geographically proximate computing services near end users to reduce network latency. Edge computing servers are often used in the context of telecommunications and optimizing mobile applications. In one embodiment, predictive models for ML and GenAI may be placed on such edge servers. Specifically, much historical data is geographically specific, and Machine Learning (ML) models including reward models for Generative AI (ML models to bias Large Language Models to a particular application) may be hosted on such edge servers based on locality.

### Cloud Service Platforms

A service on cloud 236 may provide the services of a server 218. In general, servers may either be a physical dedicated server or may be embodied in a virtual machine. In the latter case, cloud 236 may represent a plurality of disaggregated servers which provide virtual application server 238 functionality and virtual storage/database 240 functionality. The disaggregated servers are physical computer servers, which may have a processor, a memory, an I/O interface and/or a network interface. The features and variations of the processor, the memory, the I/O interface and the network interface are substantially similar to those described for server 218. Differences may be where the disaggregated servers are optimized for throughput and/or for disaggregation.

Cloud 236 services 238 and 240 may be made accessible via an integrated cloud infrastructure 242. Cloud infrastructure 242 not only provides access to cloud services 238 and 240 but also to billing services and other monetization services. Cloud infrastructure 242 may provide additional service abstractions such as Platform as a Service (“PAAS”), Infrastructure as a Service (“IAAS”), and Software as a Service (“SAAS”).

As stated above, cloud 236 services generally disaggregate physical servers and reaggregate them into virtual machines. This process is accomplished via a software component called a hypervisor. Virtual machines appear to be like a physical server, but because of the disaggregation and reaggregation process, hypervisors enable the efficient use of hardware, as the virtual machine includes only the compute, store, and automation hardware requested, leaving excess hardware capacity to be used in other virtual machines.

Because virtual machines behave like physical servers, the time to boot up the virtual machine may take an unacceptable amount of time. To this end, containerization software such as Google Kubernetes™ and Docker, enable partitions of the virtual machine (called containers), to perform compute functions on demand without boot time delay.

### Virtualization and Adaptive Resource Interfacing for Global Energy Management

Recall that Energy Orchestration relies on disaggregation of physical energy resources and the reaggregation of portions of those physical energy resources into virtual energy resources. This process is known as virtualization. Virtualization is accomplished in the aggregation server 130 via the virtual resource platform 132. FIG. 3 is a diagram 300 illustrating virtualization.

The Aggregation Server 130 is communicatively coupled to different customers, such as an office 102 or factory 108 or with a microgrid 118. The Aggregation Server 130 is also connected with the power grid at large via External Interface 134. Each customer 102, 108 has its own physical energy resources usually in the form of an IDER 304 and has its own virtual power plant comprised of a plurality of virtual energy resources 306.

The Aggregation Server 130 will either receive a request from a consumer, potentially from a mobile application or web portal via aggregation server APIs 146 for a change in energy resources or will via analytics in the Predictive Energy Manager 140 determine the need for a change in energy resources. That change in energy resources may be the deallocation of a virtual energy resource, the allocation of a virtual energy resource, or a change in the composition of a virtual energy resource. Those changes sent to the Virtual Resource Platform 132 for implementation.

Virtual Resource Platform 132 The API Layer 302 provides a software programmatic interface for the Virtual Resource Platform 132 overall. It is accessible via various programming language bindings such as via C/C++, Java, GoLang and other common programming languages. In some embodiments it may be exposed via cloud APIs where it may be scripted with scripting languages such as Python, JavaScript, and Typescript. The API Layer 302 provides access to operations to create, delete, and update virtual energy resources, reporting, diagnostics, and other administrative functions. Accordingly, the Virtual Resource Platform 132 will receive a request for a change from the Predictive Energy Manager 140 via API Layer 302.

Adaptive Interfacing of IDERs is managed via a Drivers Database 310. The Drivers Database 310 tracks the identity of specific physical energy resources to energy resource types and drivers. Accordingly, if the request to add a new IDER as a physical resource, the Virtual Resource Platform 132 identifies the energy resource type of the physical energy resource by function. Examples of energy resource types include without limitation smart meters, inverters, solar panels, wind turbines, heat pumps, and thermostats. The determination of energy resource type is accomplished via a lookup table in a Drivers Database 310 that maps make and model and other physical energy resource identifiers to energy resource type. Upon identification of the energy resource type, the Drivers Database 310 looks for the location of a software driver 312 corresponds to the IDER.

The Virtualization Database 306 tracks the physical energy resources and virtual energy resources associated with specific users. New physical resources are registered by adding records identifying a physical energy resource, its attributes, and the consumer the physical energy resource belongs to. Allocations are made via creating a record of a virtual energy resource, and allocating portions of physical energy resources to that virtual energy resource, and then serving the virtual energy resource to the requesting party, usually the Predictive Energy Manager 140. Deletion of a physical energy resource generally involves the deallocation of any virtual energy resources reliant on the physical energy resource, and then deleting the registration records of the physical energy resource. Where history audit capability is to be retained, instead of the deleting records, the Virtualization Database 306 may instead mark records as inactive along with a date-time stamp of the time when active.

Accordingly, if a received request is to add a new physical energy resource, the Virtual Resource Platform 132 registers the IDER and driver by associating it with the consumer owning the IDER in the Virtualization Database 306. Similarly, if the received request is to delete a physical energy resource, the Virtual Resource Platform 132 deallocates any related virtual energy resources reliant on the physical energy resources and then either deletes or marks as inactive the records in the Virtualization Database 306.

Once physical energy resources are registered with the Virtualization Database 306 those resources may then be subdivided, and reaggregated into virtual resources. This is accomplished via a software energy resource Allocator 308. The Allocator 308 creates, deletes, and updates records in the Virtualization Database 306 identifying the specific subdivisions of disaggregated physical energy resources, identifying a virtual energy resource comprised of a master record for the virtual energy resource and detail records of the subdivisions constituting a reaggregation, and the identify of the consumer (or virtual power plant) the virtual energy resource is allocated to. In the case of virtual power plants, the Virtualization Database 306 may store a master record for a consumer associating it with a record for a virtual power plant, which in turn stores detail records of virtual energy resources. Alternatively, the Virtualization Database 306 may delegate to a third-party database tracking virtual power plants, such as one managed by a utility.

Accordingly, where a virtual energy resource is to be allocated, the Allocator 314 receives from the API Layer 302 a request comprised of a consumer and a quantity of virtual resources to be served. Physical energy resources that are not yet allocated are identified via a best fit algorithm, and then aggregated into one or more virtual energy resources based on energy resource type. Note that the Virtualization Database 306 stores what subdivisions of physical energy resources are already allocated or otherwise in use. The Allocator 314 then stores in the Virtualization Database 306 a master record with the new virtual energy resource, detail records of the constituent portions of the physical energy resources, and a record associating the virtual energy resource with a consumer and/or consumer virtual power plant.

Deallocation of a virtual resource is the same process in reverse. Upon receiving a request from the API Layer 302 to deallocate a virtual energy resource, the Allocator 314 will update the Virtualization Database 306 by disassociating the virtual energy resource from the consumer and/or consumer virtual power plant, deleting or deactivating detail records of physical energy resource subdivisions, and deleting or deactivating the record of the virtual energy resource itself. Because the physical energy resource subdivisions are no longer associated with a virtual energy resource, the Virtualization Database 306 will indicate those physical energy resource subdivisions as available for reallocation.

Recall that the drivers 312 that interface with IDERs 304 support a standard API on a per energy resource type basis. Specifically, batteries have a standard API for the Virtual Resource Platform 132 to invoke, as do smart meters, heat pumps, solar panels, or any other consumer or generator of energy. Recall that because the physical energy resources are IDERs, they have APIs, but because they have different makes and models the APIs will vary widely. The standard API is therefore implemented in terms of the particular make and model of the physical energy resource. In this way the Virtual Resource Platform 132 is able to handle the different resource makes and models.

Note that the drivers 312 do not merely provide a consistent API interface for the Virtual Resource Platform 132, but also to the Predictive Energy Manager 140 and to the Aggregation Server 130 itself. The standard API used for each energy resource type contains APIs to retrieve usage telemetry sufficient to support the predictive statistics of the Predictive Energy Manager 140. This includes energy transfer over time, downtime, and failure events. In some cases, it is understood that some makes and models do not provide an API that supports predictive statistics. In this case, the driver may report a not-implemented error when the specific API is invoked. In this case, the Predictive Energy Manager 140 can make use of heuristics to estimate the missing statistics. An example is to make use of third-party benchmarks or performing statistical averaging over historical use of the physical energy resource or other resources of the same make and resource type. Alternatively, the driver may implement these gap filling heuristics itself.

### Intelligent Energy Profiles for Global Energy Management

An emergent property of virtualization and Energy Orchestration is Global Energy Management. Presently, consumers might be able to get reporting on individual IDERs associated with their bill and might be able to optimize individual IDERs. However, Energy Orchestration and virtualization provides visibility not only to one's virtual power plant, but also to all virtual resources available on the Aggregation Server 130, and the ability to perform optimizations not just across IDERs in one's virtual power plant, but also optimizations between different consumers. Consider the example of two schools next to each other. The two schools would not only be able to optimize their own resources but also trade and load balance. Note further that because the power plants are virtualized, there is no need for the schools to be geographically proximate. A school in London could load balance with another school in Newcastle provided that their infrastructure was virtualized and they participated on the same power grid.

The ability to collect information not just for one's virtual power plant but also to get information as to options to optimize one's energy usage holistically is called Global Energy Management. The collection of the aforementioned information to enable Global Energy Management is called an Intelligent Energy Profile. FIG. 4 is a diagram 400 illustrating Intelligent Energy Profiles and Global Energy Management.

A consumer may make use of a mobile device 402 and/or a web portal 404 to access the Aggregation Server 130. The Mobile Device 402 may have a mobile app or may simply provide a browser to access web portal 404. Regardless, the client software accesses the Aggregation Server 130 via Aggregation Server APIs 146.

The Aggregation Server 130 will have a software Intelligent Energy Profile Manager (or Profile Manager for short) 138 which will have access to Historical Usage Database 406 and User Configuration Database 408. The Historical Usage Database 406 provides historical data of the consumer's energy generation and energy consumption as well as adverse events. The User Configuration Database 408 stores information and metadata about the consumer's virtual power plant. In some cases, the User Configuration Database 408 may delegate storage and information requests to Virtualization Database 306 in the Virtual Resource Platform 132.

The Aggregation Server 130 also has access to third-party data 136 such as to billing management companies and carbon tracking companies. Access is via External Interface 134. In this way, the Aggregation Server 130 can apply analytics, not only to a consumer's virtual power plant, but all virtualized physical energy resources managed in the Virtual Resource Platform 132, and to third-party data of its choosing.

Analytics in the Aggregation Server 130 is performed by the Predictive Energy Manager 140. The Predictive Energy Manager 140 includes a Recommendation Engine 410 and various statistical algorithms 412, which can include Machine Learning and/or Generative Artificial Intelligence algorithms 414. Recall that the drivers 312 may not provide sufficient information for the statistical algorithms. For this eventuality, a software estimator 416, performs gap filling to provide estimates for missing data in the statistical algorithms according to a predetermined statistical variation tolerance. Gap filling may involve use of historical averages of similarly situated devices and energy resource types, or vendor reported data, or extrapolations from other data.

The Predictive Energy Manager 140 may be invoked with a request by the Reporting Manager 144 which in turn is called via an API call 146. For any request, the Predictive Energy Manager 140 calls the Recommendation Engine 410 which stores the logic for various report types. Report types can be pre-configured (aka “canned” or pre-programmed), or can be free-form, such as a prompt for a GenAI algorithm. Regardless of report type, the Recommendation Engine 410 manages the logic and operational flow to create a response to the request.

Upon identifying the logic of the query, the Reporting Manager 144 retrieves the relevant Intelligent Energy Profile from the Profile Manager 138 comprised of queries to the User Configuration Database 408 and the Historical Usage Database 406. Depending on the query, the Predictive Energy Manager 140 may also make queries to the Virtualization Database 306 and to external third-party data sources 136 via external interface 134. In some cases, third party data such as environmental/weather data and market/energy cost/tariff data may be accessed via third party data sources 136. The Intelligent Energy Profile Manager 138 may call application programming interfaces in the external interface software module 134 so it will have well known APIs to access the third party data sources 136.

As directed by the Reporting Manager 144, the Predictive Energy Manager 140 will apply relevant analytics algorithms 412 and 414 to the retrieved data. Based on the query logic the Reporting Manager 144 will then format the results from the algorithms into a response to the query. The Reporting Manager 144 will return the finalized report via API 146 which in turn responds to the client software on mobile device 402 and/or web portal 404.

Note that all reports from the Reporting Manager 144 make use of the Predictive Energy Manager 140 which is able to ensure rigorous statistical methodology because the Virtual Resource Platform 132 implements a driver system that guarantees inputs into the Virtual Resource Platform 132 that are used by the statistical algorithms 412, ML/GenAI 414, or otherwise applies an estimator 416 for gap filling. Accordingly, each report is generated with a confidence score. Where the confidence score does not meet a predetermined threshold, or where the statistical variance is above a predetermined threshold (i.e., where the predictive value of the report is below a predetermined utility), the Reporting Manager 144 can return a warning, an error, or simply not return a report. All too often, software applications generate predictions and statistics, but do not test for statistical significance and rigor. This can cause users to rely on reports that are inaccurate or worse are in error. This statistical check ensures this is not the case with the Aggregation Server 130 and its constituent software.

Reports from the Reporting Manager 144 include recommendations that a user may or may not opt to implement. However, in some cases, a user may wish to automate the acceptance and implementation of at least one recommendation. This is possible with IDERs which have control APIs to implement such recommendations. Where a user so configures the Predictive Energy Manager 140, recommendations from the Recommendation Engine 410 can be received by an Execution Engine 418 in the form of a script. The Execution Engine 418 is a programmatic script interpreter that can programmatically access APIs of IDERS from their respective drivers 312. Note that the Execution Engine 418 is an interpreter, and is capable of receiving recommendations in the form of byte-code and p-code for interpretation. Accordingly, references to script herein include any interpretable computer executable code, not just human readable script code. Upon receiving a script from the Recommendation Engine 410, Execution Engine 418 performs the tasks in the script, and where a IDER is to be commanded, be it for configuration or operation or telemetry, the Execution Engine 418 may call the relevant API. In this way, the Predictive Energy Manager 140 can perform active orchestration, that is automated orchestration of IDERs.

It is worthwhile to describe particular use cases to illustrate the utility of Intelligent Energy Profiles and Global Energy Management. One set of reports is simply to provide overall reporting for a virtual power plant. For example, one may review historical usage data with rolled up data for an entire virtual power plant, rather than for individual IDERs. A report can then show holistic reports not just indicating your energy consumption but can also identify devices that use a disproportionate amount of energy (aka “energy hogs.”) Note further that because information is captured in near real time, the information is guaranteed to be timely. For example, if your energy utilization is about to exceed a predetermined threshold, you can lower energy utilization immediately to address the problem, rather than discover a problem after the fact.

Another set of reports may be to make use of third-party data. Consider the example of bill validation. Oftentimes, a utility will provide erroneous bills. The Report Manager 144 can combine outside utility and billing information 134 via External Interface 136 and compare it with actual telemetry. In this way not only can billing errors be detected, but also proof provided to establish the veracity of any challenge.

Third-party data can include service level agreements (SLAs) and warrantees. While IDER vendors typically provide warrantees, most consumers presently do not have the means to verify compliance. However, because the Aggregation Server 130 may access SLAs and vendor warrantees 136 via external interface 134, historical data can be compared to those SLAs and warrantees and non-compliance automatically detected. Accordingly, this provides the means for consumers to report issues to vendors along with proof. The alternative is to operate with defective equipment or improper installations without knowledge.

A very powerful set of reports involves the application of analytics by the Predictive Energy Manager 140 to provide recommendations. Because the Predictive Energy Manager 140 has access to information of all resources in the Virtualization Database 306 the Predictive Energy Manager 140 can surface options to consumers.

Options may include showing on a mobile device 402 or web portal 404 comparative data for switching energy providers and DNOs. The client application can show actual cost savings, breakdowns of cost savings, fees to switch, and savings over time to breakeven. The client application 402, 404 can even provide graphical representations of savings. For example, a school may wish to determine whether to change electricity utilities. The savings can be represented with a graphic of teacher icons representing the number for teacher salaries that would be recovered with a utility switch.

Options may include recommendations of whether to change a user's virtual power plant configuration. A common example would be to recommend adding batteries and potentially solar panels. Not only could savings and savings over time be reported, but also recommendations for local vendors along with expected costs and financing options.

Another example would be to change IDER vendors. Not only could a Predictive Energy Manager 140 provide information as to which batteries were failing, but also recommendations for makes and models for replacement and installers.

Options may include recommendations for changes in behavior. By way of example, many utilities charge tariffs for peak energy hours. This tariff information is accessible from utilities 136 via external interface 134. The Predictive Energy Manager 140 can then identify the impact of washing clothes after peak hours, or the impact of time shifting by installing solar panels and batteries.

The above options are merely exemplary and not intended to be limiting. But as shown above, Intelligent Energy Profiles and Global Energy Management provide consumers with information external to a single consumer's virtual power plant, information for options, and analytics with data supporting courses of action. The data can be used to report problems to vendors and utilities, or to inform optimizing courses of action. Regardless of how the data is used, the result is more efficient, more economical, and more timely management of energy.

### Operation of Global Energy Management

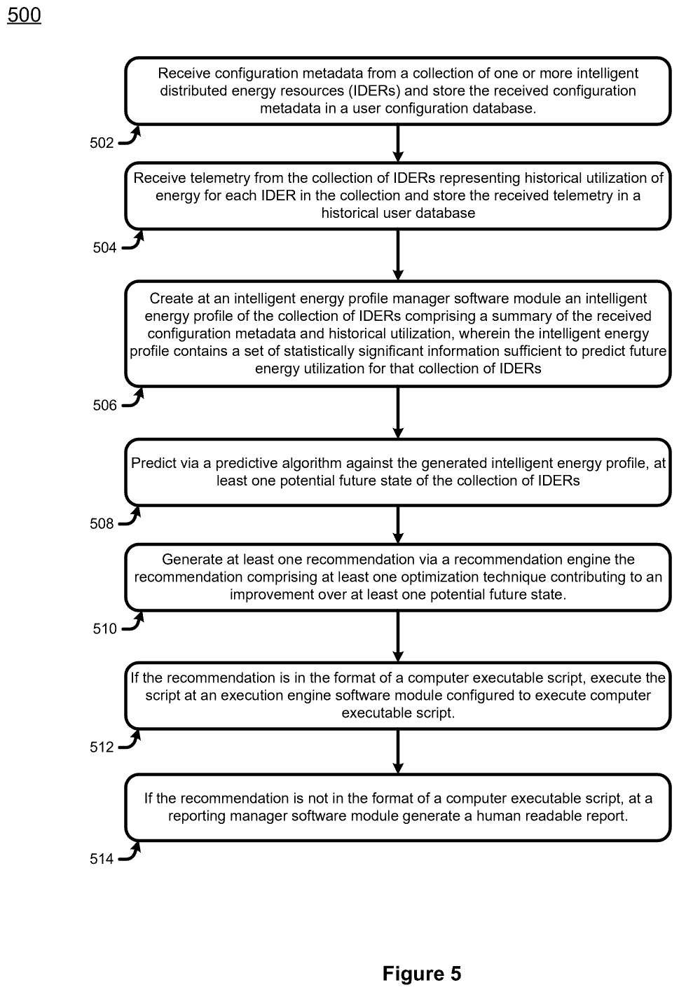

Having described the Predictive Energy Manager 140 and its components, we are not ready to discuss its operation. FIG. 5 is a flow chart 500 describing how the Predictive Energy Manager 140 collects data, creates an Intelligent Energy Profile, creates predictions, and generates recommendations.

We start with the notion of a collection of IDERs. Each IDER has a driver 312 provided by and managed by the Virtual Resource Manager 132 as described with respect to FIG. 3. These drivers provide the means to collect configuration metadata on how its respective IDER is configured, its respective energy utilization (here utilization including both energy consumption and production) history, and programmatic control for the IDER. Additionally, third party data, such as environmental/weather data, and energy cost/market/tariff data may be accessed and included for analysis. The most common collection of IDERs is for a building or a portion of a building. For each collection of IDERs a summary of its configuration and its energy utilization, called an Intelligent Energy Profile can be generated by an Intelligent Energy Profile Manager 138. An Intelligent Energy Profile not only summarizes data for the collection of IDERs it does so such that the data contained may be used to perform statistical operations to predict future states and to recommend optimizations.

Collections of IDERs in which each collection has its own Intelligent Energy Profile enables the ability to scale. A portion of a building, such as an apartment, may have a collection of IDERs with its own Intelligent Energy Profile. The apartment's collection may be itself be a subcollection aggregated by another collection of IDERs for the entire apartment building. A campus of buildings, each with their own respective collection of IDERs and their own respective Intelligent Energy Profile may be subcollections for a microgrid with its own Intelligent Energy Profile. Such scaling, such as multiple microgrids may continue up to the entire national grid.

In block 502 the user configuration database 408 collects metadata about individual IDERs. IDER metadata settings may include make and model, but also user settings, and operating parameters. Because each IDER is accessed via its own driver 312, and because the driver 312 has standardized APIs the user configuration database 408 knows which APIs with which to retrieve any desired metadata.

In block 504 the historical usage database 406 collects energy utilization data for each IDER. Here utilization may mean production or alternatively consumption. Note that some IDERs are both producers and consumers of electricity. As with IDER metadata, because each IDER is accessed via its own driver 312, and because the driver 312 has standardized APIs the user configuration database 408 knows which APIs with which to retrieve any desired historical usage data. Note that in some cases, there may be gaps in data. Accordingly, a software estimator 416 may be used for gap filling as described with respect to FIG. 4. Specifically, similar devices and/or similarly situated devices with available data may be aggregated and estimates made as to what the missing data is most likely to have been. For example, the software estimator 416 based on the make and model of the IDER find IDERs with similar operating parameters. The software estimator 416 may apply the inputs of the IDER with the missing data to the similar/similarly-situated IDERs and generate estimates used to gap fill the missing data.

As stated above, the Intelligent Energy Profile can include accessing utility DNO/DSO information as well as contextual information such as environmental/weather data and market/energy cost/tariff data. This data is generally accessed via third party data sources 136. The Intelligent Energy Profile Manager 138 may call application programming interfaces in the external interface software module 134 so it will have well known APIs to access the third party data sources 136.

In block 506, an intelligent energy manager software module accesses for a collection of IDERs configuration metadata from the user configuration database 408, and historical usage data from the historical usage database 406. This data is converted to a summary format organized into rows and columns. Each row has consistent fields, and each row represents a measurement. The rows and columns in this way provide a dataset. This dataset can in turn be used to train an AI, provide retrieval augmented generation (RAG) data for a GenAI, or simply be used for non-AI statistical analysis. Regardless of the method used, the dataset comprising the intelligent energy profile provides a statistically significant amount of data to enable predictions and recommendations.

In block 508, either a non-AI statistical algorithm is selected from a set of predetermined statistical algorithms 412, or a machine learning or GenAI algorithm is used 414, to make a prediction of a future state of the collection of IDERs. A future state can include whether a condition such as a weather change will occur to trigger a spike of energy utilization (e.g., high outside heat causes the need for energy for air conditioning, or a snowstorm in which there is a need for a driveway defroster). In general, predictions will focus on whether there is a need for energy or whether there is excess energy for returning for net metering.

In the case of GenAI, a GenAI application comprising a language model, such as a large language model, and a reinforcement learning neural net may be used. The GenAI application receive a prompt, the prompt may be modified using preloaded data in a retrieval augmentation generation buffer. The prompt may make a request for at least one prediction based on one or more predictive algorithms. Because the GenAI application can generate multiple predictions, those predictions may be amalgamated into a single prediction.

Once a prediction is made concerning the future state of the collection of IDERs, block 510 is concerned with generating a recommendation with a recommendation engine software module 410. A recommendation is where an improvement over the future state of the collection of IDERs can be specified. To clarify what is meant by improvement, a predetermined object function, such as minimize energy utilization, minimize carbon emissions, or minimize energy cost can be selected. Where the predetermined object function shows that application of an optimization will provide a more optimal future states of the collection of IDERs (i.e., less energy used), that recommendation can be returned.

Different users will have different levels of confidence in the recommendations returned by the recommendation engine 410. Some will wish to automated the implementation of the recommendations while others may wish to review the recommendations prior to any implementation.

The Predictive Energy Manager 140 can be configured for automatic execution of recommendations from recommendation engine 410. In this way the Predictive Energy Manager 140 may provide active orchestration - that is a fully automated feedback loop to dynamically reconfigured IDERs and collection of IDERs for optimization. Note that the recommendation engine 410 can generate optimizations in any textual format including computer executable scripts. In block 512, if the recommendation is in computer executable script form, it is forwarded to Execution Engine 418. Execution Engine 418 is a script interpreter (e.g., JavaScript interpreter, python interpreter), which automates the recommended optimization. Note that optimizations most likely will include reading IDERs and commanding IDERs. This is accomplished via the scripts and Execution Engine 418 invoking APIs in the IDER drivers 312 managed by the Virtual Resource Manager 132.

Alternatively, in block 514, the recommendation is not a computer script to be executed. In this case, a Reporting Manager software module 144 is used to create a formatted human readable output (known as “pretty printing”) and is returned to the user for evaluation.

### Adaptive Location Independent Global Energy Management Mechanisms

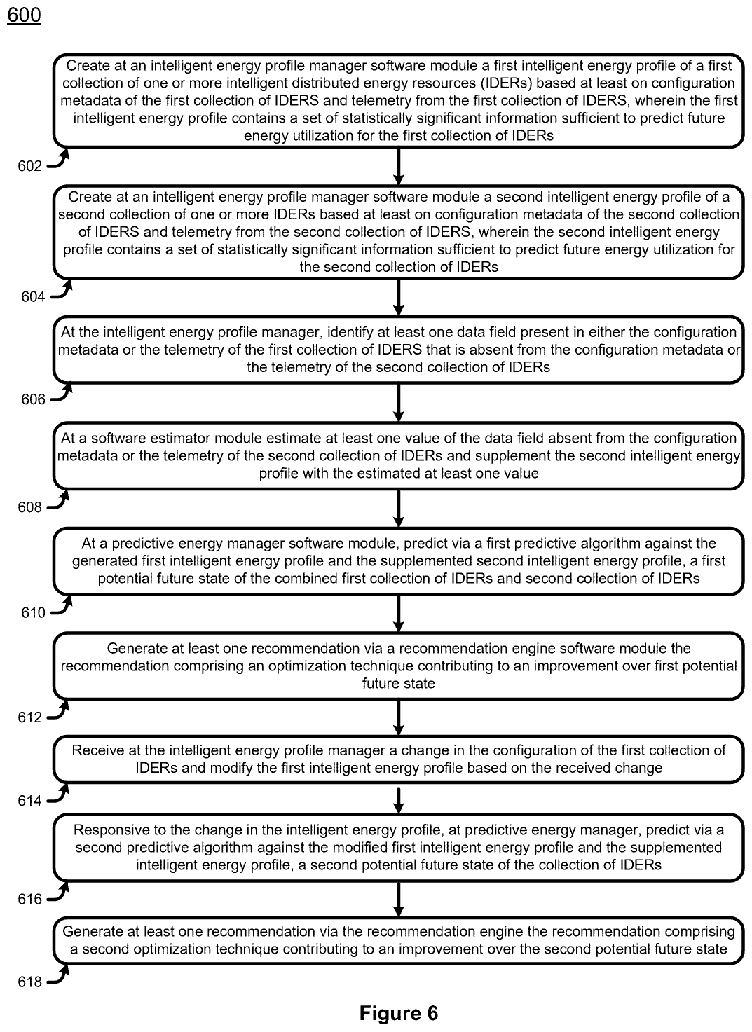

The concepts behind Global Energy Management come from the perspective that while individuals will privately choose whether or not to virtualize their energy resources into IDERs and when and how to do so, public policy still retains responsibility for ensuring that energy infrastructure optimizes energy generation and transfer along with responsibilities to the environment and society at large. Because of virtualization, regulators and public administrators may have access to data coming from IDERs. Note however that these IDERs may be aggregated independent of location. For example, a private party may have three solar farms each in three different states and may seek to aggregate all three farms together. Individual IDERs such as a set of solar panels in a farm can change over time. Most certainly, aggregations can change over time. For example, a solar farm may be sold or an additional one bought. In these dynamic scenarios, Global Energy Management exhibits a degree of adaptiveness not available in the prior art. FIG. 6 is a flow chart 600 illustrating the exemplary operation of adaptive location independent energy management mechanisms.

In blocks 602 and 604, an intelligent energy profile is made for a first collection of IDERs and second collection of IDERs respectively. The process to create an intelligent energy profile is as described with respect to FIG. 5 blocks 502, 504, and 506. As stated above, collected IDERs need not be in the same geographic locality and collections.

One of the issues of IDERs being collected by different parties is that there is no guarantee that the data fields in first collection of IDERs will correspond with the data fields in the second collection of IDERs. If fields are not present in one collection of IDERs, but are present in another, we can either create an estimate values for the missing field (called “gap filling”) or we can omit the data fields without correspondences. The problem with omission is that we deny ourselves the benefit of the existing data. Accordingly, in Global Energy Management, a Software Estimator 416 is used to fill in corresponding missing data with estimates.

In block 606, the Intelligent Energy Profile Manager 138 compares the data fields comprising the data being received, including configuration metadata and historical energy utilization data (which itself includes data from third parties). It may use an ontology (a lookup table of data field synonyms) to find corresponding data fields and may select a data field type to accommodate the original data field types. However, where the Intelligent Energy Profile Manager 138 identifies that a data field is present in the data from a first collection of IDERs, for example because no match in an ontology can be found, in block 608, the Intelligent Energy Profile Manager 138 uses the Software Estimator 416 to fill in values. Value filling may be performed by identifying similar IDERs or similarly situated IDERs and using their data to make a trend line based on inputs. The IDER with the missing data can have an estimate generated using interpolation or extrapolation on the trend line. The result is that the second intelligent energy profile is now supplemented with the estimate from the Software Estimator 416.

Data may also be missing due to differing sampling rates between the collections of IDERs. For example, a first collection may sample once an hour, and another every 15 minutes. Trendlines can be generated and missing data from the first collection (i.e., samples for every 15 minutes) and be interpolated. Future projections of data may be extrapolated from the trend lines. Note that trendlines need not be linear but may include curves accordingly to selected statistical distributions. In some cases, the statistical distribution may be selected via a Generative AI algorithm. In this way data may be extrapolated and/or projected using a GenAI application.

In block 610 a Predictive Energy Manager 140 makes a prediction for a potential future state of the combined first and second collections of IDERs and in block 612 a Recommendation Engine is used to make a recommendation comprising an optimization technique. Blocks 610 and 612 operate analogously to FIG. 5 blocks 508 and 510 except that multiple Intelligent Energy Profiles are evaluated. Note that in this case, one of the Intelligent Energy Profiles includes supplemented values from the Software Estimator 416. Further note that the collections of IDERs need not be geographically proximate. In this way, we are able to generate recommendations that are not only adaptive, but also location independent.

Note that a collection of IDERs and the constituent IDERs themselves may change over time. Global Energy Management provides for adaptation under such circumstances as well. Recall that the Intelligent Energy Profile Manager 138 is in communication with the Historical Usage Database 406 and the User Configuration Database 408. In block 614, the Intelligent Energy Profile Manager 138 receives a notification that an IDER in a collection of IDERs has changed. In response, the Energy Profile Manager 138 modifies the relevant Intelligent Energy Profiles. Where an Intelligent Energy Profile adds an IDER, data from the new IDER is added to the profile and missing data gap filled used the Software Estimator 416. Where an IDER is removed, similarly the related data is removed and any aggregated calculations (e.g., sum, average, max, min) are recalculated. Where an IDER changes or is modified generally the Energy Profile does not change historical data, but collects data moving forward with the new configuration. However, if an administrator so specifies, historical data may be removed, missing data gap-filled with the Software Estimator 416, and aggregated calculations recalculated.

Now that the Intelligent Energy Profiles have been updated, in block 616, responsive to the updates, the Predictive Energy Manager 140 makes a prediction for a subsequent potential future state of the combined first and second collections of IDERs, and in block 618 the Recommendation Engine is used to make a recommendation comprising an optimization technique.

Blocks 615 and 616 operate analogously to blocks 610 and 612 above and FIG. 5 blocks 508 and 510.

Note that as in FIG. 5 block 512, the Recommendation Engine may generate an executable script embodying the recommendation. If so configured, script may be executed by Execution Engine 418. In doing so, we have described energy management that adapts to any reconfiguring of a collection of IDERs, changes to IDERs, changes to circumstances (e.g., responding to historical energy usage data) regardless of location of the IDERs.

### Energy Accounting System

One deficiency in present energy management systems is that they report financial information, such as potential savings, but do not make use of public accounting standards. While for residential and unsophisticated consumers, such ad hoc reporting of financial data may be sufficient. However, when managing large amounts of data across multiple users, for example for commercial, industrial, and governmental/public applications, this is not sufficient. In the case of the Aggregation Server 130, because it has visibility across multiple consumers and virtual power plants, the Aggregation Server 130 associates energy resources and their associated costs with those multiple consumers and virtual power plants. This gives rise to the application of accounting methods which excel at attributing costs as to make proper inferences from financial data.

To this end, an Energy Accounting System 142 is disclosed. Specifically, the Energy Accounting System 142 supports national and globally accepted accounting standards such as Generally Accepted Accounting Principles (GAAP) and Financial Reporting Standards (FRS). This allows for unified and native accounting operations such as activity-based cost accounting and managerial and financial accounting for energy transactions. Combined with an exchange mechanism, the energy management system via an Aggregation Server 130 would provide a platform to perform energy transactions.

FIG. 7 provides a diagram 700 for the Energy Accounting System 142 and its context.

The Energy Accounting System 142 provides a General Ledger 702 and a Chart of Accounts 704 to organize entities to attribute credits and debits. The General Ledger 702 and Chart of Accounts 704 may be implemented as database tables and records. In one embodiment, a Chart of Accounts 704 may be a table in a relational database where each child account references the index of its parent account, and the General Ledger 702 are detail records of credits and debits indexed to the relevant Chart of Accounts 704 account. In other embodiments a cross-reference table stores the relationship of the child and parents accounts in the Chart of Accounts 704.

Accordingly, the Energy Accounting System 142 interfaces with the Intelligent Energy Profile Manager 138 to provide classification information to attribute energy credits and debits; with the Predictive Energy Manager 140 and Reporting Manager 144 to respond to queries for reports, and with the APIs and Administrative Module 146 for maintaining the General Ledger 702 and Chart of Accounts 704.

Note that terminology may be different between customers, vendors, and other entities. Accordingly, an Ontology Engine 706 implemented as a terminology database, stores different terminology and resolves that terminology to a standard term recognized by the General Ledger 702 and Chart of Accounts 704. Specifically, when the Energy Accounting System 142 receives an unknown term, it can query the Ontology Engine 706, identify whether the term is recognized or not, and if recognized, retrieve the standard term associated with the incoming term. If a term is not recognized, an administrator can determine whether to update the Ontology Engine 706.

The Energy Accounting System 142 receives representations of the provenance of energy from outside sources. Furthermore, as energy from different sources are mixed and matched through the reaggregation and virtualization processes set forth with respect to FIG. 3 above, characterizing whether energy meets certain requirements, such as whether the energy comes from green or brown sources, becomes obscured. To protect the integrity of the Energy Accounting System 142, and otherwise to ensure that outside data is trustworthy and will not corrupt internal data, the Energy Accounting System 142 implements a software cryptographic capable Certification Manager 708. Specifically, when energy enters the Aggregation Server 130, either from the outside power grid 136, from DNOs 136, or internally generated by IDERs managed by the Virtual Resource Platform 132, the Certification Manager 708 creates a cryptographic certificate for that energy representing the quantity and provenance of the energy and any metadata to characterize the energy. An example of a characterization would be whether the energy is green energy, brown energy, or otherwise.

The generated certificate can then be associated with records on a software Audit Log 710 implemented on a database. The Audit Log 710 store metadata and information about the provenance, quantity, and characterization of the associated energy that will not fit on a certificate, or otherwise should be easy to access via a database interface. The Audit Log 710 also stores the customer consuming the energy and how the remaining energy is reaggregated. As energy is reaggregated, new certificates can be generated that are associated with the relevant portion of aggregated energy. In this way, a chain of custody of the provenance of each portion of reaggregated energy can not only be tracked but also tracked in a trusted fashion.

The Energy Accounting System 142 equipped with a Certification Manager 708 and Audit Log 710 gives rise to various exemplary use cases.

One example is the notion of a Carbon Net Zero system. For a particular installation, some subsets of customers can be collected into what is characterized by Carbon Net Zero, that is to say that the consumption of energy is attributed to green sources or from green carbon credits. Because the Energy Accounting System 142 issues certificates via the Certification Manager 708 attesting to source and whether the source is green or not, the Aggregation Server 130 can determine whether consumption matches incoming green sources. If it does not, the Aggregation Server 130 may be configured to interface with third-party carbon exchanges to purchase offsets or otherwise get to Net Zero. Because the Energy Accounting System 142 is fine-grained, that is it continues to track green status across virtualization and reaggregation, there is no loss of energy attributed to green sources.

In general, Carbon Net Zero and carbon economy participation is possible because of the rigors imposed by an Energy Accounting System 142. Consider for example Sustainable Development Goal (SDG) reporting which has its own requirements for compliance. Such compliance is only possible with rigorous provenance checking.

Another example is the notion of tokenizing energy generation and other related activities. Because the Certificate Manager 708 generates cryptographic certificates for all incoming energy, including generated energy, those certificates may in turn be tokenized, that is converted into exchangeable cryptographic artifacts that may be traded. In some embodiments the tokens may underlie a cryptographic currency. In other embodiments the tokens may be traded in of themselves. Users of such tokens need only have user records created in the Intelligent Energy Profile Manager 138, and the tokens associated with the relevant profiles. The Audit Log 710 tracks utilization. When the energy underlying the token is consumed, the record of the token is either destroyed or deactivated.

The aforementioned examples are not intended to be limiting. Rather the examples are illustrative of some emergent properties. Because energy transactions are tracked according to Generally Accepted Accounting Principles or equivalent accounting regimes, reporting across multiple consumers and entities is possible in a disciplined fashion. For example, credits and debits of energy can be tracked via double entry bookkeeping. Furthermore, enterprises with accounting compliance requirements need not translate ad hoc reports into GAAP or equivalent compliant reporting.

Beyond reporting, because the Energy Accounting System 142 provides cryptographic grade certifications to track provenance, interfacing with the carbon economy, or cryptographic currency economy, or any other economy is enabled. In short, the Energy Account System 142 provides compliant and fine-grained reporting for energy input including generation and consumption.

### Global Energy Management, Privacy, and Cybersecurity

Global Energy Management relies on data to be able to perform the statistics that underly predictions and recommendations. However, users rightfully may request data associated with their accounts deleted. This of course can compromise having the information basis for perform the statistics that underly predictions and recommendations. Upon deletion the predictive capabilities of the Aggregation Server 130 should fail gracefully, i.e., allowances for less accurate predictions should be made by the software infrastructure until the variances are no longer acceptable.

Turning back to FIG. 1, the Aggregation Server 130 includes a software Security Engine 148 that handles encryption, and tracks when data is deleted. The Reporting Manager 144 and the Predictive Energy Manager 140 are communicatively coupled with the Security Engine 148.

Specifically, the Security Engine 148 performs cryptographic key generation and key management for user accounts and manages encryption at rest for user profile data and user personal data if applicable. When a user requests deletion of data, the Security Engine 148 stores a database log as to what data is removed, in particular from the Historical Usage Database 406 and the User Configuration Database 408. As stated above, the software Security Engine 148 interfaces with the Intelligent Energy Profile Manager 138 and the Predictive Energy Manager 140 to do so.

Accordingly, if the Reporting Manager 144 or the Predictive Energy Manager 140 receive a request from a user, the Reporting Manager 144 or the Predictive Energy Manager 140 may query the Security Engine 148 to determine whether data has been deleted. If some or all data has been deleted, the Reporting Manager 144 or the Predictive Engine may invoke the software estimator 416 to gap fill as described in FIG. 4 above. If the estimator 416 cannot gap fill within a predetermined threshold of variance, that is to say that the gap filling will result in a statistical error to obviate reliability and the benefit of prediction, then an error is returned. In this case, a client application may decide to hide or otherwise disable the predictive feature.

The “right to be forgotten” that is the right for a consumer to have personal data and data attributable to the user to be delete in demand is codified in various laws, most notably the General Data Protection Regulation (GDPR) in the European Union. Versions of this right apply through analogous law in other jurisdictions such as the United Kingdom and various states in the United States. All too often, software application developers know that predictive capabilities, through machine learning, GenAI, or traditional statistical algorithms are compromised from data deletion, but fail to address this risk. The aforementioned system and techniques describe and approach that checks for predictive accuracy with graceful failover as users exercise their rights to be forgotten.

### Business Use Cases for Global Energy Management

Energy Orchestration and Global Energy Management implemented by the Aggregation Server 130 enable many business use cases. In particular Three specific use cases are described below without limitation.

A first use case is around the Aggregation Server 130 providing a monetization platform to enable users to be fully informed in switching energy providers. While the Aggregation Server 130 provides comparative information about energy providers and DNOs, an obstacle is in encouraging users to install an application on their mobile device 402 that accesses the Aggregation Server 130 in the first place.

In one embodiment, a mobile application is provided in a freemium and in a paid premium application. The freemium application provides enough information as to whether a user should switch energy providers. Specifically, the application indicates historical usage, historical costs, and alternative providers. Data for historical usage and historical costs is obtained from the Historical Usage Database 406. Information from the alternative providers may be obtained through External Interface 134.

The application can provide not just costs of alternative providers and related issues, but also automate the switch. Specifically, the application can make a request to the Aggregation Server 130 to run a server-side application executed on the Script Execution Engine 150. The server-side application interfaces with different energy providers via External Interface 134 to effect an automated switch.

Since the application provides the instant gratification of immediate savings through switching energy providers, users are motivated to install the freemium application. Costs for promoting the freemium application may be underwritten through contracts with energy providers that pay a commission or bounty for motivating users switching to their services. Because the server-side application performs the actual switch, the server-side application can provide auditable proof that the customer switching should be attributable to the application and therefore should be paid commission.

Now with the application installed, the user may then discover other ways to save. The freemium application may then surface historical savings of other similarly situated users as an incentive for a user to switch to the paid for premium application. Upon subscription, the premium application will then provide both long term and real time recommendations for changes of vendors, configuration, behavior and the like as described with respect to FIG. 4 above. The set of users that convert to the paid for premium application constitutes the basis for a commercial going concern.

Another business scenario relates to providing a web portal for public institutions such as grade schools. Because the Aggregation Server 130 does not require users to be geographically proximate, and because virtualization enables the arbitrary aggregation of users, a set of grade schools, even ones geographically disparate can be aggregated together. Those grade schools thus aggregated can then shift energy from one school to another. Furthermore, the grade schools can receive recommendations with respect to energy provider, vendor, configuration, and behavior to minimize costs. In this way, a paid subscription service for access to the Aggregation Server 130 can be financially justified.

An emergent property of aggregating disparate schools together is the ability of those schools to collectively negotiate a bulk rate for energy that would otherwise not be possible by a single school. Because the Aggregation Server 130 maintains an Energy Accounting System 142, attribution of energy sources and energy consumption is reliably tracked.

Another emergent property of aggregating disparate schools together is collective participation in the carbon economy. Because the aggregated schools may report carbon emissions, compliance with carbon emissions can be load balanced by exchanging energy between schools and ultimately, if necessary, collectively negotiating carbon credits and offsets.

As a final note, it is observed that schools often are located based on population density. Versions of the freemium and premium business model described above can be simultaneously marketed to parents of students at the schools.

The business models described above are just two possible business models enabled by Energy Orchestration and Global Energy Management as implemented by the Aggregation Server 130. These examples are not intended to be limiting but rather to illustrate broad applicability.

### CONCLUSION

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A computer-implemented method to perform Global Energy Management, comprising each of the following as executed by a computer:
creating at an intelligent energy profile manager software module an intelligent energy profile of a collection of one or more intelligent distributed energy resources (IDERs) based at least on configuration metadata of the collection of IDERS and telemetry from the collection of IDERS, wherein the intelligent energy profile contains a set of statistically significant information sufficient to predict future energy utilization for the collection of IDERs;
at a predictive energy manager software module, predicting via a first predictive algorithm against the generated intelligent energy profile, a first potential future state of the collection of IDERs; and
generating at least one recommendation via a recommendation engine software module the recommendation comprising a first optimization technique contributing to an improvement over the first potential future state.

2. The method of claim 1, wherein the received telemetry includes historical energy utilization data from the collection of IDERS.

3. The method of claim 2, wherein the historical energy utilization data includes third-party data.

4. The method of claim 3, wherein the third-party data is any one of: utility data, energy market data, and energy tariff data.

5. The method of claim 2, wherein the historical energy utilization data includes either data where a software estimator module was utilized to add interpolated data or extrapolated data to provide data otherwise missing from the telemetry.

6. The method of claim 1, wherein the first optimization technique includes an optimization balancing a plurality of objective functions.

7. The method of claim 6, wherein the first predictive algorithm was implemented via a generative artificial intelligence application via prompting a language model combined with a reinforcement learning model.

8. The method of claim 6, comprising:
receiving at an execution engine software module configured to execute computer executable script, the at least one recommendation in the format of a computer executable script;
executing at the execution engine the received computer executable script; and
where the computer executable script directs the access of an application programming interface for an IDER, calling the application programming interface via a driver managed by a virtual resource manager.

9. The method of claim 1, comprising:
receiving at the intelligent energy profile manager a change in the configuration of the collection of IDERs;
at the intelligent energy profile manager modifying the intelligent energy profile based on the received change;
responsive to the change in the intelligent energy profile, at the predictive energy manager, predicting via a second predictive algorithm against the modified intelligent energy profile, a second potential future state of the collection of IDERs; and
generating at least one recommendation via the recommendation engine the recommendation comprising a second optimization technique contributing to an improvement over the second potential future state.

10. The method of claim 9, wherein the second optimization technique includes an optimization balancing a plurality of objective functions.

11. The method of claim 10, wherein the first predictive algorithm was implemented via a generative artificial intelligence application via prompting a language model combined with a reinforcement learning model.

12. The method of claim 11, comprising:
receiving at an execution engine software module configured to execute computer executable script, the at least one recommendation in the format of a computer executable script;
executing at the execution engine the received computer executable script; and
where the computer executable script directs the access of an application programming interface for an IDER, calling the application programming interface via a driver managed by a virtual resource manager.

13. A method to perform Global Energy Management, comprising:
creating at an intelligent energy profile manager software module a first intelligent energy profile of a first collection of one or more intelligent distributed energy resources (IDERs) based at least on configuration metadata of the first collection of IDERS and telemetry from the first collection of IDERS, wherein the first intelligent energy profile contains a set of statistically significant information sufficient to predict future energy utilization for the first collection of IDERs;
creating at an intelligent energy profile manager software module a second intelligent energy profile of a second collection of one or more IDERs based at least on configuration metadata of the second collection of IDERS and telemetry from the second collection of IDERS, wherein the second intelligent energy profile contains a set of statistically significant information sufficient to predict future energy utilization for the second collection of IDERs;
at a predictive energy manager software module, predicting via a first predictive algorithm against the generated first intelligent energy profile and the generated second intelligent energy profile, a first potential future state of the combined first collection of IDERs and second collection of IDERs; and
generating at least one recommendation via a recommendation engine software module the recommendation comprising an optimization technique contributing to an improvement over the first potential future state.

14. The method of claim 13, comprising:
at the intelligent energy profile manager, identifying at least one data field present in the configuration metadata of the first collection of IDERS that is absent from the configuration metadata of the second collection of IDERs;
at a software estimator module estimating at least one value of the data field absent from the configuration metadata of the second collection of IDERs.

15. The method of claim 14, wherein the software estimator module's estimation includes identifying at least one IDER in the second collection of IDERs that is similarly situated to an IDER in the first collection of IDERs and inferring the value of the data field absent from the configuration metadata of the second collection of IDERs.

16. The method of claim 14, comprising:
at the intelligent energy profile manager, identifying at least one data field present in the telemetry of the first collection of IDERS that is absent from the telemetry metadata of the second collection of IDERs;
at a software estimator module estimating at least one value of the data field absent from the telemetry of the second collection of IDERs.

17. The method of claim 16, wherein the software estimated module's estimate includes identifying at least one IDER in the second collection of IDERs that is similarly situated to an IDER in the first collection of IDERs and inferring the value of the data field absent from the telemetry of the second collection of IDERs.

18. The method of claim 16, wherein the software estimated module's estimate includes identifying at least one IDER in the second collection of IDERs that is similarly situated to an IDER in the first collection of IDERs and extrapolating the value of the data field absent from the telemetry of the second collection of IDERs.

19. The method of claim 13 wherein the first collection of IDERs or the second collection of IDERs or both are comprised of geographically disparate IDERs.

20. One or more computer-readable storage media collectively having thereon computer-executable instructions that, when executed, collectively cause one or more computers to, at least:
create at an intelligent energy profile manager software module an intelligent energy profile of a collection of one or more intelligent distributed energy resources (IDERs) based at least on configuration metadata of the collection of IDERS and telemetry from the collection of IDERS, wherein the intelligent energy profile contains a set of statistically significant information sufficient to predict future energy utilization for the collection of IDERs;
at a predictive energy manager software module, predict via a first predictive algorithm against the generated intelligent energy profile, a first potential future state of the collection of IDERs;
generate at least one recommendation via a recommendation engine software module the recommendation comprising a first optimization technique contributing to an improvement over the first potential future state
receive at the intelligent energy profile manager a change in the configuration of the collection of IDERs;
at the intelligent energy profile manager modify the intelligent energy profile based on the received change;
responsive to the change in the intelligent energy profile, at the predictive energy manager, predict via a second predictive algorithm against the modified intelligent energy profile, a second potential future state of the collection of IDERs; and
generate at least one recommendation via the recommendation engine the recommendation comprising a second optimization technique contributing to an improvement over the second potential future state.
